(19) United States
(12) Patent Application Publication
(10) Pub. No.: US 2016/0163590 A1
(43) Pub. Date: Jun. 9, 2016

(54) METHODS OF MANUFACTURING SEMICONDUCTOR DEVICES

(71) Applicant: Samsung Electronics Co., Ltd., Suwon-si (KR)

(72) Inventors: Deokyoung Jung, Seoul (KR); Seong-Min Son, Hwaseong-si (KR); Jin-Ho An, Seoul (KR); Byung-Lyul Park, Seoul (KR); Ji-Soon Park, Suwon-si (KR); Ho-Jin Lee, Hwasung-City (KR)

(21) Appl. No.: 14/956,869

(22) Filed: Dec. 2, 2015

(30) Foreign Application Priority Data
Dec. 4, 2014 (KR) 10-2014-0173021

(51) Int. Cl. H01L 21/768

(52) U.S. Cl. CPC H01L 21/76877; H01L 21/76822

(57) ABSTRACT

Disclosed is a method of manufacturing a semiconductor device. A preliminary wafer-carrier assembly is formed in such a way that a wafer structure having a plurality of via structures is adhered to a light-penetrating carrier by a photodegradable adhesive. A wafer-carrier assembly having an optical shielding layer for inhibiting or preventing a light penetration is formed such that the wafer structure, the carrier and the adhesive are covered with the optical shielding layer except for the backside of the wafer structure through which the via structures are exposed. An interconnector is formed on the backside of the wafer structure such that the via structures make contact with the interconnector, and the wafer structure and the carrier are separated from each other by irradiating a light to the wafer-carrier assembly. Accordingly, the adhesive is inhibited or prevented from being dissolved during a plasma process on the wafer-carrier assembly.

### CROSS-REFERENCE TO RELATED APPLICATIONS

This application claims under 35 U.S.C. §119 to Korean Patent Application No. 10-2014-0173021, filed on Dec. 4, 2014, the disclosure of which is incorporated by reference herein in its entirety.

### BACKGROUND

Example embodiments relate to a method of manufacturing semiconductor devices, and more particularly, to a method of manufacturing semiconductor devices having a penetrating member such as a through silicon via (TSV) structure.

As the recent electronic systems devices tend to be downsized together with high performance, there has been intensive research for increasing the memory capacity of semiconductor devices as well as for increasing the integration degree of memory chips.

A chip stack technology by using a penetrating member such as the through silicon via (TSV) has been widely used for increasing the memory capacity of the semiconductor packages. The limitations of the conventional microfabrication technology restrict the increase of integration degree of the memory chips and the signal delay due to the elongation of the wirings also limits the stack degree increase of the memory chips in the semiconductor package. For those reasons, the penetrating member has been widely applied to chip stack packages for increasing the memory capacity of the semiconductor packages without the signal delay.

However, the conventional chip stack technology using the penetrating member faces various problems in grinding the wafers. In the conventional TSV process, the wafer is mounted onto a carrier by using an adhesive member and the TSV process for forming the TSV through the wafer is performed to the assembly of the carrier and the wafer. However, the adhesive member tends to be dissolved in the TSV process and thus various defects caused by the dissolution of the adhesive member are generated in the TSV process.

### SUMMARY

Example embodiments of the present inventive concept provide a method of manufacturing semiconductor devices for preventing the dissolution of the adhesive member in a plasma process for forming a penetrating member, thereby minimizing a swelling defect and an arching defect at an edge portion of the wafer.

According to exemplary embodiments of the inventive concept, there is provided a method of manufacturing semiconductor devices including a penetration electrode. A preliminary wafer-carrier assembly may be formed in such a way that an active face of a wafer structure having a plurality of via structures may be adhered to a front surface of a light transmitting carrier by a photodegradable adhesive and a backside of the wafer structure opposite to the active face may face upwards. A wafer-carrier assembly having an optical shielding layer for preventing a light transmission may be formed in such a way that the wafer structure, the carrier and the adhesive may be covered with the optical shielding layer except for the backside of the wafer structure through which the via structures may be exposed. An interconnector may be formed on the backside of the wafer structure in such a way that the via structures may make contact with the interconnector, and the wafer structure and the carrier may be separated from each other by irradiating a light to the wafer-carrier assembly.

In an example embodiment, the wafer-carrier assembly having the optical shielding layer may be formed by the following steps. A rear portion of the wafer structure including the backside may be partially removed from the preliminary wafer-carrier assembly, until the via structures are exposed, and then the preliminary wafer-carrier assembly may be turned over in such a way that a rear surface of the carrier opposite to the front surface may face upwards. The optical shielding layer may be formed along a surface profile of the preliminary wafer-carrier assembly such that side surfaces of the carrier, the adhesive and the wafer structures may be covered with the optical shielding layer.

In an example embodiment, the optical shielding layer may be formed on the preliminary wafer-carrier assembly by one of spin-on-coating (SOC) process and a deposition process.

In an example embodiment, the wafer-carrier assembly having the optical shielding layer may be formed as follows: The preliminary wafer-carrier assembly may be immersed into a solution having solutes of optical shielding particles, thereby forming a material layer along a surface profile of the preliminary wafer-carrier assembly. Then, the material layer may be dried in a dry process, thereby forming the optical shielding layer on the preliminary wafer-carrier assembly. The optical shielding layer and a rear portion of the wafer structure under the optical shielding layer may be partially removed from the preliminary wafer-carrier assembly, thereby exposing the backside of the wafer structure and the via structures.

In an example embodiment, the optical shielding layer and the rear portion of the wafer structure may be partially removed by one of grinding process, a chemical mechanical polishing (CMP) process and an etch-back process.

In an example embodiment, the photodegradable adhesive may include a double-sided adhesive tape interposed between the active face of the wafer structure and the carrier.

In an example embodiment, the photodegradable adhesive may be configured to be self-released by an ultraviolet light.

In an example embodiment, the ultraviolet light may include a wavelength in a range of 350 nm to 400 nm.

In an example embodiment, the carrier may include one of glass and quartz.

In an example embodiment, the optical shielding layer may include a conductive material.

In an example embodiment, the conductive material may include a carbon-based polymer.

In an example embodiment, the optical shielding layer may be configured to prevent a light having a wavelength of 350 nm to 400 nm from reaching the wafer-carrier assembly, so that the photodegradable adhesive may be prevented from self-releasing in a plasma process to the wafer-carrier assembly.

In an example embodiment, the interconnector may be formed as follows. A rear portion of the wafer structure including the backside may be partially etched from the backside in such a way that the via structures may protrude from the backside. An insulation layer may be formed along a surface profile of the protruded via structures such that the neighboring via structures may be electrically insulated from each other, and a passivation layer may be formed on the insulation layer such that a gap space between the neighboring via structures may be filled with the passivation layer. The passivation layer and the insulation layer may be planarized until a top surface of the via structure is exposed, and a conductive pattern may be formed on each of the via structures.

In an example embodiment, the rear portion of the wafer structure may be partially etched off by a plasma etching process.

In an example embodiment, the insulation layer may include an oxide layer and the passivation layer may include a nitride layer.

In an example embodiment, the conductive pattern structure may include a metallic bump structure and re-directional wirings on the backside of the wafer structure.

In an example embodiment, the wafer structure and the carrier may be separated from each other as follows: The optical shielding layer may be partially removed from a rear surface and a side portion of the carrier, thereby partially exposing the carrier, and the light may be irradiated into the exposed carrier, thereby dissolving the photodegradable adhesive interposed between the carrier and the wafer structure. Then, the wafer structure and the carrier may be dissembled from each other.

In an example embodiment, the optical shielding layer may be partially removed by a wet etching process.

In an example embodiment, the light may have a wavelength of 350 nm to 400nm and may be irradiated from an upper portion of the wafer-carrier assembly such that the light may penetrate through the carrier and reaches the adhesive.

In an example embodiment, after separating the wafer structure and the carrier, one of additional wafer structure and a circuit board may be further stacked on the separated wafer structure.

According to other exemplary embodiments of the inventive concept, there is provided a method of manufacturing a semiconductor device. The method includes: forming a preliminary wafer-carrier assembly comprising a wafer structure and a light transmissive carrier, with a backside of the wafer adhered to a front surface of the carrier by a photodegradable adhesive; forming a wafer-carrier assembly having an optical shielding layer that covers the carrier and at least a portion of the wafer structure, wherein the optical shielding layer is configured to block light having a wavelength of about 350 nm to about 400 nm from reaching the photodegradable adhesive; partially removing the optical shielding layer from a rear surface and a side portion of the carrier such that a portion of the carrier is exposed; and separating the wafer structure and the carrier by irradiating light to the exposed portion of the carrier.

In an example embodiment, before partially removing the optical shielding layer, the optical shielding layer may cover the rear surface and a side portion of the carrier, a side portion of the photodegradable adhesive, and a side portion of the wafer structure.

In an example embodiment, the optical shielding layer may be formed on the preliminary wafer-carrier assembly by one of a spin-on-coating (SOC) process and a deposition process.

In an example embodiment, the wafer structure may include a plurality of via structures, and the method may include, after forming the wafer-carrier assembly having the optical shielding layer and before partially removing the optical shielding layer, forming an interconnector on the backside of the wafer structure such that the via structures make contact with the interconnector.

In an example embodiment, forming the wafer-carrier assembly having the optical shielding layer may include: immersing the preliminary wafer-carrier assembly in a solution having solutes of optical shielding particles to form a material layer along a surface profile of the preliminary wafer-carrier assembly; drying the material layer to form the optical shielding layer on the preliminary wafer-carrier assembly; and partially removing the optical shielding layer and a rear portion of the wafer structure under the optical shielding layer to expose the backside of the wafer structure and the via structures.

According to example embodiments of the present inventive concept, the wafer structure may be adhered to the carrier by a photodegradable adhesive tape in place of the conventional adhesive deposition layer, thereby reducing the manufacturing cost of the wafer-carrier assembly for forming a penetration electrode in the semiconductor device. Particularly, the light penetration carrier may be provided with the wafer-carrier assembly and thus the photodegradable adhesive may be sufficiently self-released by a dissolving light that may penetrate through the carrier from exterior of the wafer-carrier assembly. In addition, the wafer-carrier assembly may be covered with the optical shielding layer for inhibiting or preventing the light in the plasma process from penetrating through the carrier, so that the photodegradable adhesive may be sufficiently prevented from dissolving in the plasma process. Accordingly, the swelling and the arching defect between the wafer structure and the carrier in the plasma process may be inhibited or prevented.

### BRIEF DESCRIPTION OF THE DRAWINGS

These and other features of the inventive concept will become more apparent by describing in detail exemplary embodiments thereof with reference to the accompanying drawings of which:

FIG. 1 is a flow chart showing a method of manufacturing semiconductor devices in accordance with a first example embodiment of the present inventive concept;

FIG. 2 is a cross sectional view illustrating the step of forming a preliminary assembly of a wafer and a carrier shown in FIG. 1;

FIGS. 3A to 3C are cross sectional views illustrating processing steps for forming the wafer-carrier assembly in accordance with a first example embodiment of the present inventive concept;

FIGS. 4A to 4C are cross sectional views illustrating processing steps for forming the wafer-carrier assembly in accordance with a second example embodiment of the present inventive concept;

FIGS. 5A to 5D are cross sectional views illustrating processing steps for forming an interconnector in accordance with an example embodiment of the present inventive concept; and

FIGS. 6A to 6D are cross sectional views illustrating processing steps for separating the wafer structure and the carrier in accordance with an example embodiment of the present inventive concept.

### DETAILED DESCRIPTION OF THE EMBODIMENTS

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element or component is referred to as being “on,” “connected to,” “electrically connected to,” or “coupled to” to another element or component, it may be directly on, connected to, electrically connected to, or coupled to the other element or component or intervening elements or components may be present. In contrast, when an element or component is referred to as being “directly on,” “directly connected to,” “directly electrically connected to,” or “directly coupled to” another element or component, there are no intervening elements or components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular example embodiments only and is not intended to be limiting of the inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

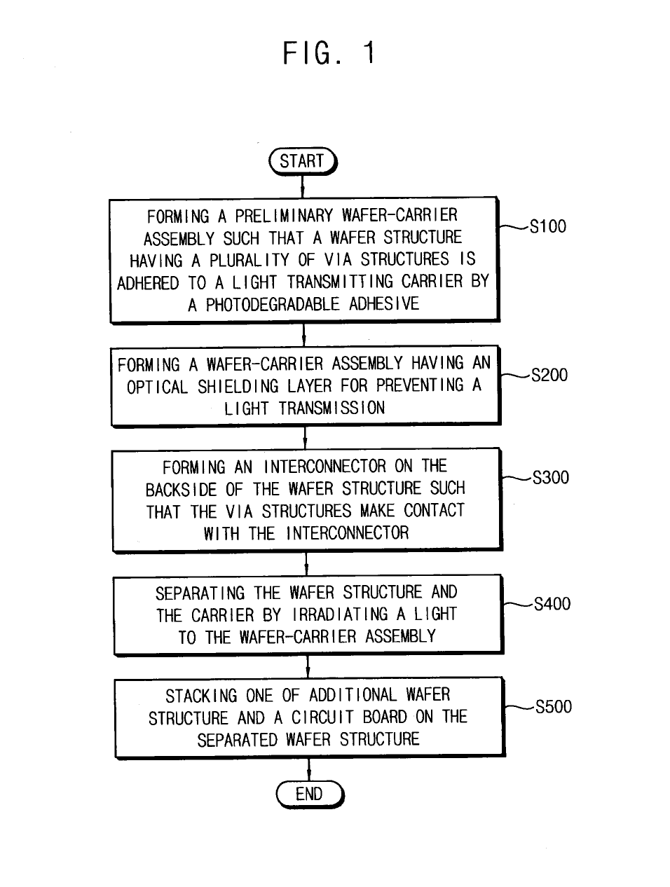

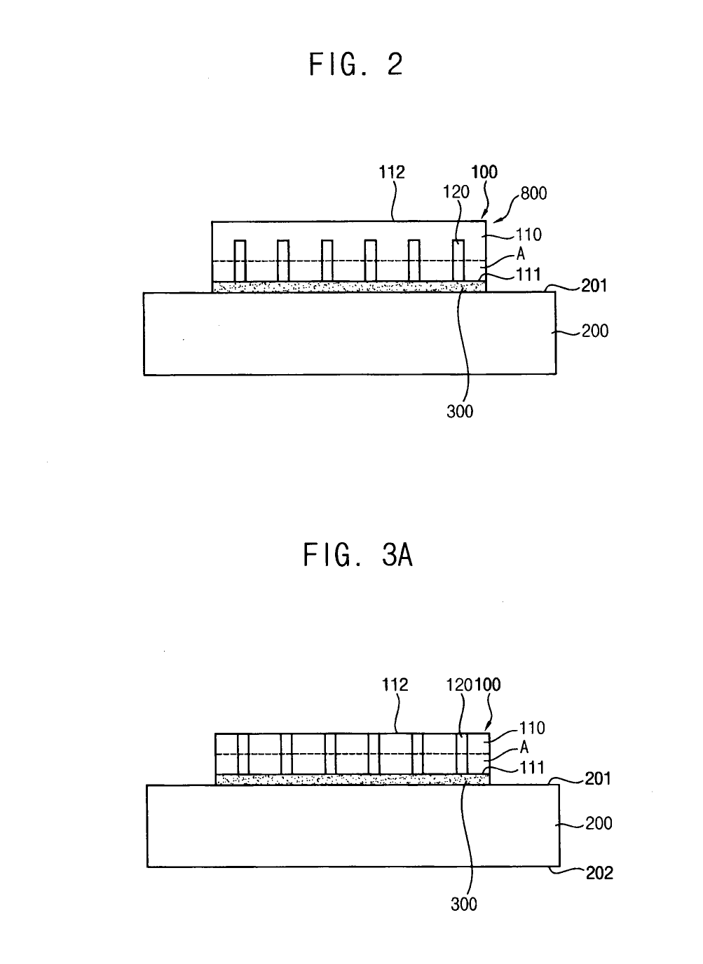

FIG. 1 is a flow chart showing a method of manufacturing semiconductor devices in accordance with a first example embodiment of the present inventive concept. FIGS. 2 to 6D are cross sectional views illustrating processing steps for the method of manufacturing semiconductor devices shown in FIG. 1. FIG. 2 is a cross sectional view illustrating the step of forming a preliminary assembly of a wafer and a carrier shown in FIG. 1.

Referring to FIGS. 1 and 2, a preliminary wafer-carrier assembly 800 may be formed in such a configuration that a backside of a wafer structure may face upwards (step S100). A plurality of via structures 120 may be formed in or on a semiconductor wafer 110 by a semiconductor manufacturing process, thereby forming the wafer structure 100 and a light transmitting carrier 200 through which a light may transmit may be provided as a base in a penetration electrode process. The wafer structure 100 may be adhered to a front surface 201 of the carrier 200 by a photodegradable adhesive 300 in such a configuration that the backside 112 of the wafer structure 100 opposite to an active face 111 of the wafer structure may face upwards.

For example, the wafer structure 100 may further include various conductive structures and various wiring lines for electrically connecting the conductive structures on the wafer 110.

The semiconductor wafer 110 may include a pure silicon substrate and a composite semiconductor substrate such as silicon-on-insulator (SOI) substrate, a silicon-germanium (Si—Ge) substrate, a silicon-carbide (Si—C) substrate and a gallium-arsenic (Ga—As) substrate.

The conductive structures and the wiring lines may be provided on the active face 111 of the wafer 110 and the backside 112 of the wafer 110 may be located opposite to the active face 111. A structure area A may be prepared at a depth of the wafer 110 and the conductive structures and the wiring lines may be arranged in the structure area A of the wafer 110.

For example, a plurality of integrated chips and wiring structures that may be insulated from one another by insulation interlayers may be arranged at the structure area A of the wafer 110 and protection layers may be provided on the insulation layers to protect the chips and the wirings from surroundings. Thus, the wafer structure 100 may include a memory device such as a dynamic random access memory (DRAM) device, a static random access memory (SRAM) device and a flash memory device. Further, the wafer structure 100 may also include a chip structure for a central process unit (CPU), a digital signal processor (DSP), an application specific integrated circuit (ASIC) device, a micro electro mechanical system (MEMS) and a photo-electronic device.

The via structure 120 may extend down into the wafer 110 to a depth from the active face 111 of the wafer 110 and may comprise electrical conductive materials. For example, a plurality of vertical holes may be formed on the active face 111 of the wafer 110 and the vertical holes may be filled with the conducive materials, thereby forming the via structures 120. The via hole may be formed by a dry etch process such as a deep reactive ion etch (DRIE) process. Examples of the electrical conductive materials may include silver (Ag), gold (Au), copper (Cu), tungsten (W), aluminum (Al), indium (In), etc.

The via structure 120 may function as a penetration electrode for electrically connecting the conductive structures and wirings of the wafer structure 100 with those of other wafer structure and a circuit board. In the present example embodiment, the via structure 120 may be shaped into a plug that may be located at a depth of about 150 μm to about 200 μm from the active face 111 of the wafer 110 with a cross sectional area of about 250 μm² to about 300 μ².

A plurality of contact pads may be arranged on the active face 111 and the backside 112 of the wafer 110 and the via structure 120 may make contact with the contact pad. Thus, an external conductive member may be electrically connected with the via structure 120 using the contact pad. Front pads on the active face 111 are not illustrated in FIG. 2 for ease of discussion and rear pads on the backside 112 may be formed in a process detailed hereinafter.

The carrier 200 may have strength and rigidity sufficient for supporting the wafer structure 100 and may be shaped into a plate having a sufficient adhesive area for the wafer 110.

Particularly, the carrier 200 may have optical penetration property, and thus the adhesive arranged on the front surface 201 of the carrier 200 may be sufficiently dissolved by the light although the light may be irradiated onto a rear surface or a side portion of the carrier 200.

For example, the carrier 200 may include a glass and quartz, and the front surface 201 may have a surface area larger than the surface area of the wafer 110. While the present example embodiment discloses the glass and quartz for the carrier 200, any other materials may also be utilized for the carrier 200 as long as the strength and the rigidity may be sufficient for supporting the wafer structure 100 and the light may penetrate through the carrier 200.

The wafer structure 100 and the carrier 200 may be adhered to each other by an adhesive 300. For example, the active face 111 of the wafer 110 may be coated with the adhesive 300 and then may be attached or combined to the front surface 201 of the carrier 200, thereby assembling the active face 111 of the wafer structure 100 to the front surface 201 of the carrier 200.

For example, the adhesive 300 may include a photodegradable material that may be self-released by a light and may be interposed between the wafer structure 100 and the carrier 200 as an adhesive layer or an adhesive tape. In case of the adhesive layer, adhesive materials may be deposited or coated on the active face 111 of the wafer 110 and thus the adhesive area and the adhesive force may be accurately controlled. In case of the adhesive tape, a double-sided tape having a uniform thickness may be adhered to one of the wafer structure 100 and the carrier 200, thereby improving the adhesion facility and efficiency in assembling the wafer structure 100 and the carrier 200.

In the present example embodiment, the adhesive 300 may include a UV self-released adhesive tape that may be self-released or self-releasing by an ultraviolet (UV) light having a wavelength of about 350 nm to about 400 nm. Particularly, the double-sided adhesive tape may cover a whole area of the active face 111, so that the carrier 200 may be easily assembled to the wafer structure 100 just by bringing the carrier into contact with the double-sided adhesive tape.

In such a case, the active face 111 of the wafer structure 100 may face the front surface 201 of the carrier 200, and thus the backside 112 of the wafer structure 100 may be exposed to surroundings in the preliminary wafer-carrier assembly 800. Particularly, the preliminary wafer-carrier assembly 800 may be arranged in such a configuration that the backside 112 of the wafer structure 100 may face upwards.

Then, a wafer-carrier assembly 900 having an optical shielding layer 400 for preventing a light penetration may be formed in such a way that the wafer structure 100, the carrier 200 and the adhesive 300 may be covered with the optical shielding layer 400 except for the backside 112 of the wafer structure 100 through which the via structures 120 may be exposed (step S200).

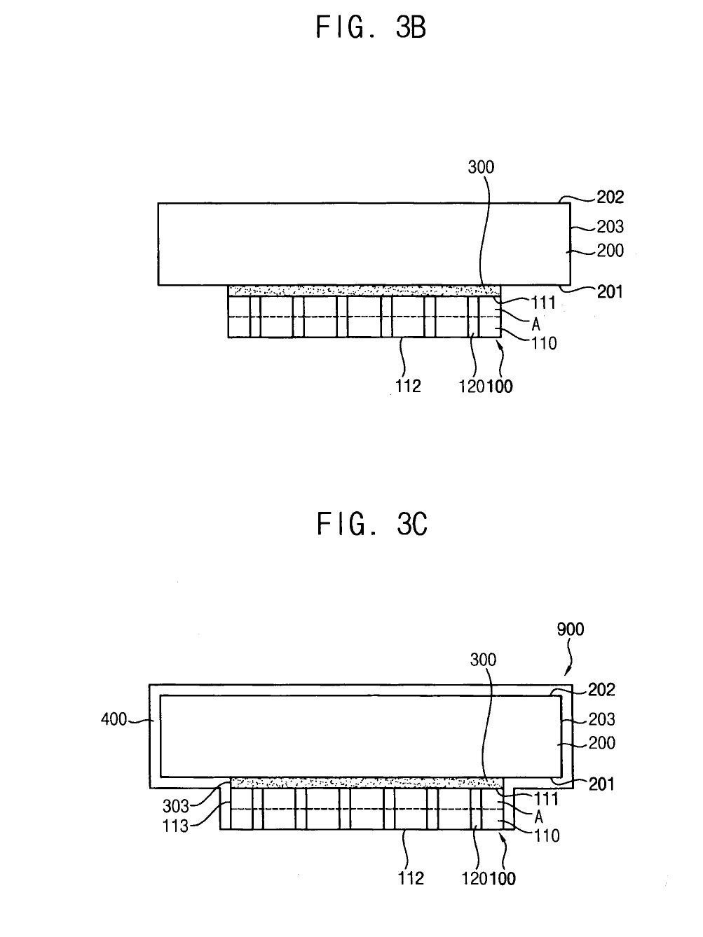

FIGS. 3A to 3C are cross sectional views illustrating processing steps for forming the wafer-carrier assembly in accordance with a first example embodiment of the present inventive concept.

Referring to FIGS. 1, 2 and 3A to 3C, a rear portion of the wafer structure 100 including the backside 112 may be partially removed from the preliminary wafer-carrier assembly 800 until the via structures 120 may be exposed, and then the preliminary wafer-carrier assembly 800 may be turned over in such a way that a rear surface 202 of the carrier 200 opposite to the front surface 201 may face upwards.

For example, the rear portion of the preliminary wafer-carrier assembly 800 may be partially removed by a grinding process, a chemical mechanical polishing (CMP) process and an etch-back process, until a thickness of the wafer 110 may be reduced sufficiently for exposing the via structures 120 at or through the backside 112 of the wafer 110. Thereafter, the preliminary wafer-carrier assembly 800 may be turned over by using an over-turn device and may be located on a support in such a configuration that the wafer structure 100 may face downwards and the rear surface 202 of the carrier 200 may face upwards.

Then, as illustrated in FIG. 3C, the optical shielding layer 400 may be coated on the preliminary wafer-carrier assembly 800 along a surface profile thereof, thereby forming the wafer-carrier assembly 900 enclosed by the optical shielding layer 400 except for the backside 112 of the wafer structure 100. The whole area of the rear and side surfaces 202 and 203 of the carrier 200 may be covered with the optical shielding layer 400 and the front surface 201 of the carrier 200 may be partially covered with the optical shielding layer 400. In addition, a side portion or surface 303 of the adhesive 300 and a side portion or surface 113 of the wafer structure 100 may be wholly covered with the optical shielding layer 400. Therefore, only the backside 112 of the wafer structure 100 may not be covered with the optical shielding layer 400 in the wafer-carrier assembly 900.

That is, since the backside 112 of the wafer structure 100 may make contact with the support, the optical shielding layer 400 may be coated on all of the non-contact areas of the wafer-carrier assembly 800 that may not make contact with the support.

The optical shielding layer 400 may be formed on the preliminary wafer-carrier assembly 800 by one of a spin-on-coating (SOC) process and a deposition process. For example, optical shielding materials may be provided onto the rear surface 202 of the carrier 200 while the support on which the preliminary wafer-carrier assembly 800 may be located may be rotated at high speed. Thus, the optical shielding materials may flow on outer surfaces of the preliminary wafer-carrier assembly 800 along the surface profile thereof, thereby forming the optical shielding layer 400 on the outer surface of the preliminary wafer-carrier assembly 800. Thus, the optical shielding layer 400 may be formed on all of the exposed outer surfaces of the preliminary wafer-carrier assembly 400 except for the backside 112 of the wafer structure 100 that may make contact with the support.

Otherwise, the optical shielding layer 400 may be formed by a deposition process in place of the SOC process. For example, a sub-atmospheric chemical vapor deposition (SACVD) process, a low pressure chemical vapor deposition (LPCVD) process and an atomic layer deposition (ALD) process may be utilized for forming the optical shielding layer 400.

Particularly, the optical shielding layer 400 may be formed on the outer surfaces of the preliminary wafer-carrier assembly 800 much more densely than the SOC process, so that the optical shielding layer 400 by the deposition process may inhibit or prevent the light generated in a subsequent plasma process from penetrating through the carrier more sufficiently and accurately than the optical shielding layer 400 by the SOC process.

Thus, the light may be sufficiently prevented from reaching the photodegradable adhesive 300 through the light penetrating carrier 200 when performing the plasma process, so that the adhesive 300 may be sufficiently prevented from being dissolved in the plasma process. When the adhesive may be dissolved in the plasma process and thus an edge portion of the wafer structure 100 may be separated from the carrier 200, the edge portion of the active face 111 may be promptly damaged by the plasma. According to the wafer-carrier assembly 900 of the present inventive concept, the adhesion force between the wafer structure 100 and the carrier 200 may be maintained in spite of the light in the plasma process by the optical shielding layer 400 and thus the edge damage of the wafer structure 100 may be sufficiently minimized in the plasma process.

The wafer structure 100 may be strongly and stably adhered to the carrier 200 in the plasma process by the adhesive 300. However, the wafer structure 100 may need to be easily separated from the carrier 200 after the plasma process. Since the adhesive 300 may include photodegradable materials that may be self-released by a light having a predetermined wavelength, the light may be prevented from reaching the adhesive 300 in the plasma process and may be allowed to reach the adhesive 300 after the plasma process. Thus, the carrier 200 may include light penetrating material and the optical shielding layer 400 may prevent the light penetration through the carrier 200.

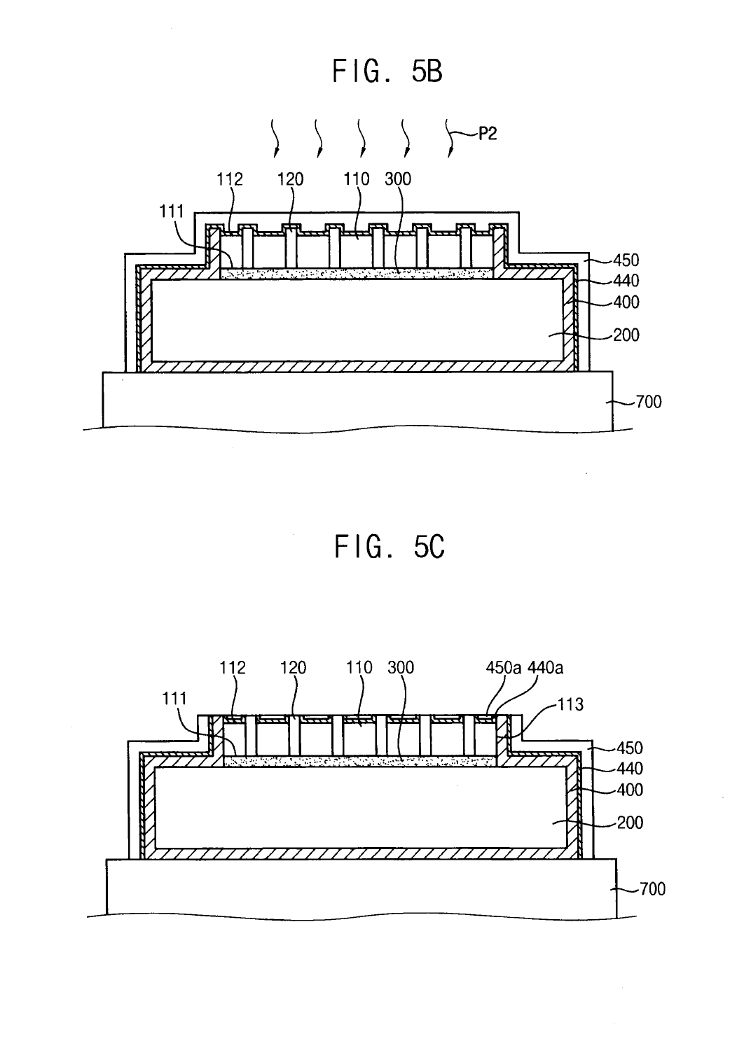

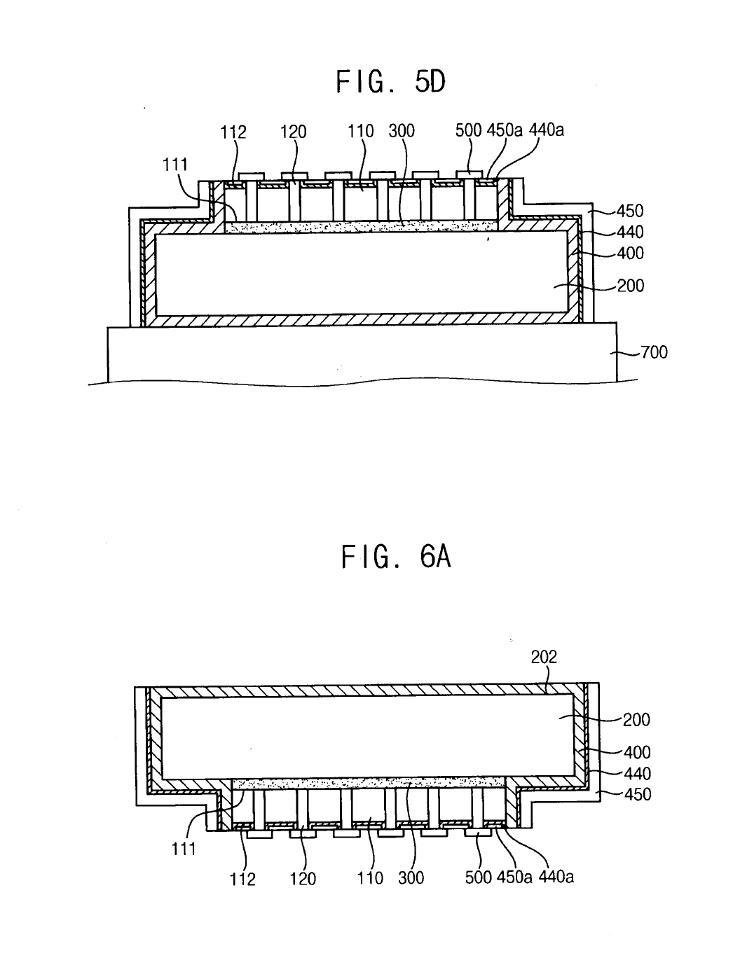

In the present example embodiment, a nitrogen (N) plasma process may be performed for forming the interconnector 500 (see, e.g., FIG. 5D) making contact with the via structure 120 and a light generated from the nitrogen (N) plasma process may have a wavelength of about 365 nm to about 370 nm. Since the adhesive 300 may include an adhesive tape that may be self-released by the light having a wavelength of about 350 nm to about 400 nm, the adhesive 300 may be sufficiently dissolved in nitrogen (N) plasma process when the light penetrates through the carrier 200.

The optical shielding layer 400 may prevent the light from penetrating the carrier 200 and thus may prevent the light from reaching the adhesive 300. In the present example embodiment, the adhesive 300 may be self-released by the UV light having a wavelength of about 350 nm to about 400 nm, and the optical shielding layer 400 may comprise a material that may be optimized for shielding a light having a wavelength of about 350 nm to about 400 nm. Thus, the shielding wavelength of the optical shielding layer 400 may be varied according to the wavelength of the self-release of the adhesive 300.

In addition, the optical shielding layer 400 may also formed into a conductive layer in such a way that the support such as an electrostatic chuck may be electrically connected to the wafer-carrier assembly 900 in the plasma process. That is, the optical shielding layer 400 may function as a lower electrode in the plasma process.

In a conventional process, an additional electrode layer such as an indium tin oxide (ITO) layer is formed on the rear surface 202 of the carrier 200 by a sputtering process. However, the ITO layer tends to be etched away in a cleaning process for forming the interconnectors 500 and thus the sputtering process needs to be periodically conducted for supplementing the etched ITO layer, which significantly increases the process complexity and cost of the interconnector process.

According to the present process for forming the wafer-carrier assembly 900, the optical shielding layer 400 may be formed into a conductive layer and function as a lower electrode layer for the plasma process, thus no additional electrode layer such as the ITO layer may be required. Therefore, the process complexity and high cost due to the ITO layer defects and the replacement of the defective ITO layer may be sufficiently reduced.

The optical shielding layer 400 may include a carbon-based polymer. However, any other conductive materials as well as the carbon-based polymer may also be utilized for the optical shielding layer 400 as long as the dissolving light by which the adhesive 300 may be self-released may be sufficiently prevented.

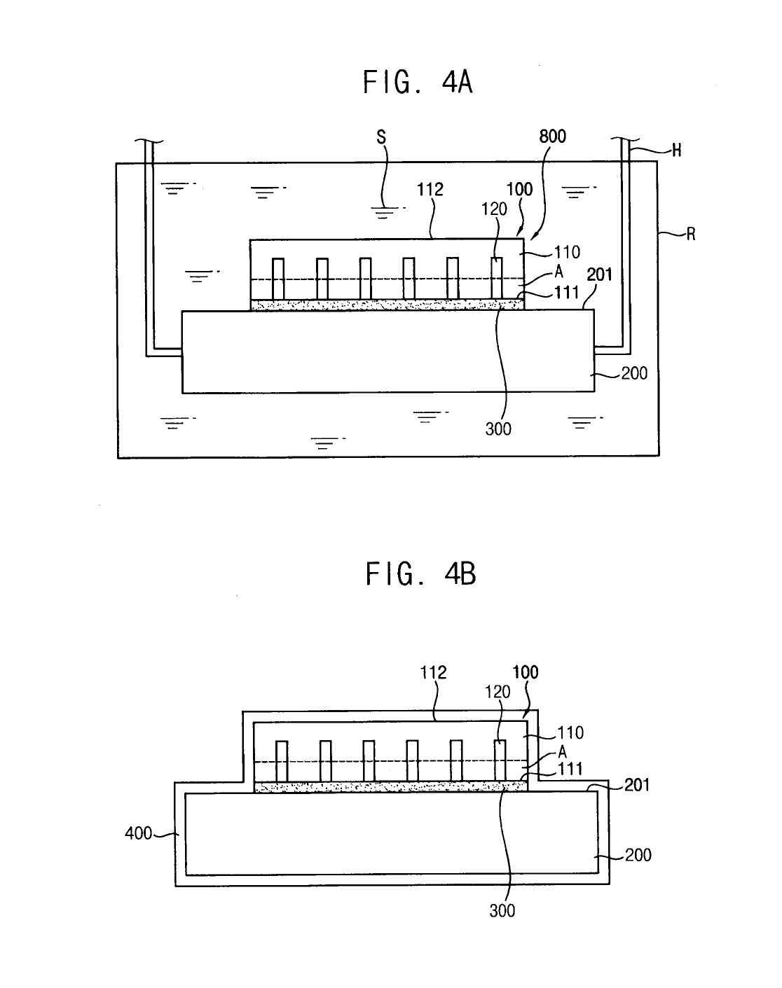

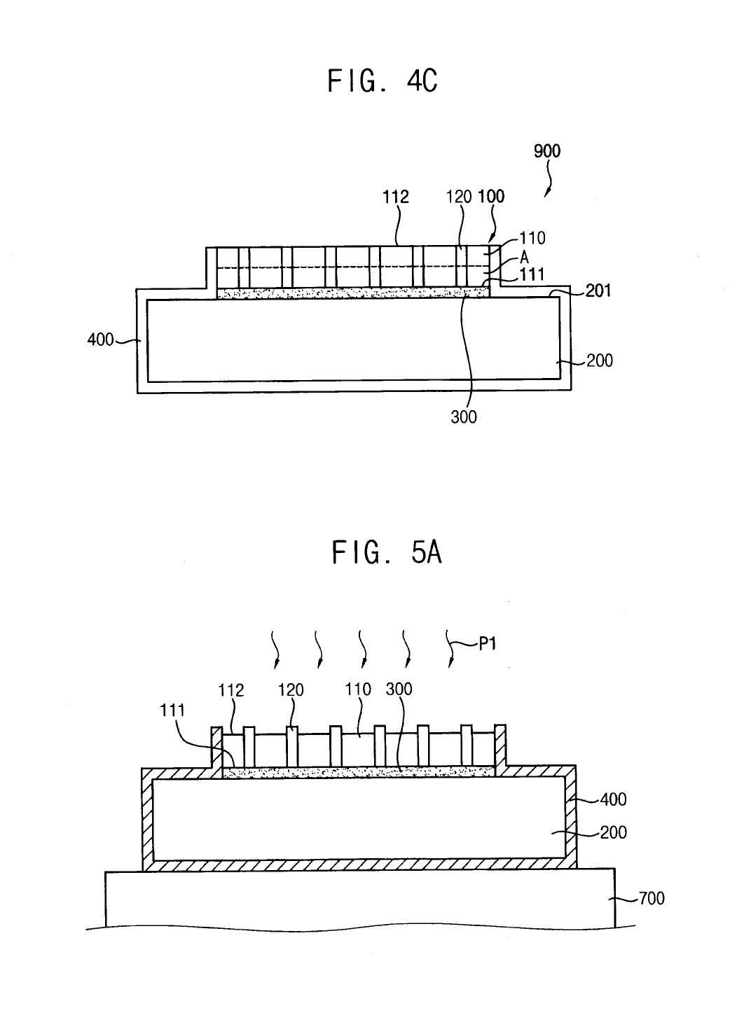

FIGS. 4A to 4C are cross sectional views illustrating processing steps for forming the wafer-carrier assembly in accordance with a second example embodiment of the present inventive concept.

Referring to FIGS. 1 and 4A to 4C, the preliminary wafer-carrier assembly 800 may be immersed into a solution S having solutes of optical shielding particles, thereby forming a material layer along a surface profile of the preliminary wafer-carrier assembly 800. Then, the material layer may be dried to form the optical shielding layer 400 on the preliminary wafer-carrier assembly 800.

For example, the preliminary wafer-carrier assembly 800 may be secured to a holder or holding member H and then the holder H may move into a reservoir R in such a way that the preliminary wafer-carrier assembly 800 may be fully immersed in the solution S in the reservoir R. When the preliminary wafer-carrier assembly 800 may be sufficiently soaked with the solution including the optical shielding particles, the holder H may be removed (e.g., pulled up) from the reservoir R and the preliminary wafer-carrier assembly 800 may be sufficiently covered with the material layer including the optical shielding particles. Thereafter, a drying process may be performed to the preliminary wafer-carrier assembly 800 covered with the material layer, to thereby form the optical shielding layer 400 enclosing the preliminary wafer-carrier assembly 800 as shown in FIG. 4B.

Then, the optical shielding layer 400 and a rear portion of the wafer structure 100 under the optical shielding layer 400 may be partially removed from the preliminary wafer-carrier assembly 800, until exposing the backside 112 of the wafer structure 100 and the via structures 120. For example, the rear portion of the wafer structure 100 including the backside 112 and the optical shielding layer 400 on the backside 112 may be grinded off from the preliminary wafer-carrier assembly 800, so that the thickness of the wafer 110 may be reduced until the via structures 120 may be exposed, to thereby form the wafer-carrier assembly 900. In modified example embodiments, the optical shielding layer 400 may be removed in advance from the backside of the wafer structure 100 by a CMP process and/or an etch-back process until the backside 112 of the wafer structure 100 may be exposed, and then the exposed backside 112 may be grinded off from the preliminary wafer-carrier assembly 800 until the via structures 120 may be exposed.

Then, an interconnector 500 may be formed on the backside 112 of the wafer structure 100 in such a way that the via structures 120 may make contact with the interconnector 500.

FIGS. 5A to 5D are cross sectional views illustrating processing steps for forming the interconnector in accordance with an example embodiment of the present inventive concept.

Referring to FIGS. 1 and 5A to 5D, the backside 112 of the wafer structure 100 may be partially etched off from the wafer 110 in such a way that the via structures 120 may protrude from a top surface of the backside 112. Then, the insulation layer 440 and the passivation layer 450 may be sequentially formed on the wafer-carrier assembly 900 in such a way that the exposed via structures 120 may be sufficiently covered with the insulation layer 440 and the passivation layer 450.

For example, the wafer-carrier assembly 900 may be loaded onto an electrostatic chuck 700 in a plasma process chamber, and a plasma etching process P1 may be performed to the wafer-carrier assembly 900. Thus, the backside 112 of the wafer structure 100 may be partially removed and a top surface of the backside 112 may be lowered without any etching against the via structures 120. Therefore, an upper portion of the via structures 120 may protrude from the reduced top surface of the backside 112 of the wafer structure 100. In such a case, the optical shielding layer 400 may function as a lower electrode for the plasma etching process P1.

Then, the insulation layer 440 may be formed on the wafer-carrier assembly 900 along a surface profile of the protruded via structures 120, so that the neighboring via structures 120 adjacent to each other may be electrically insulated by the insulation layer 440. Then, a passivation layer 450 may be formed on the insulation layer 440 in such a way that a gap space between the neighboring via structures 120 may be filled with the passivation layer 450. The insulation layer 440 may have sufficiently good junction characteristics with respect to the wafer 110, so that the detachment between the wafer 110 and the passivation layer 450 may be sufficiently prevented by the insulation layer 440.

The insulation layer 440 and the passivation layer 450 may be formed on the wafer-carrier assembly 900 by a plasma deposition process P2, and the optical shielding layer 400 may also function as an electrode layer for the plasma deposition process P2. The passivation layer 450 may be planarized by a planarization process, so that a top surface of the passivation layer 450 may be flat. In the present example embodiment, the insulation layer 440 may include a silicon oxide layer and the passivation layer 450 may include a silicon nitride layer.

The passivation layer 450 may protect the backside of the wafer structure 100 from external shocks and moistures. In addition, the passivation layer 450 may also protect the via structures 120 and the underlying conductive structures from environments for a subsequent process for forming the interconnectors 500.

Particularly, the wafer-carrier assembly 900 may be further covered with the insulation layer 440 and the passivation layer 450, thereby minimizing the defects of the wafer 110 in the plasma process. Although the wafer 110 may be etched off by the plasma etching process and thus the thickness of the wafer 110 may be reduced, the side portion 113 of the wafer 110 may be further covered with the insulation layer 440 and the passivation layer 450, thus the wafer 110 may be sufficiently protected from the following plasma process and the defects such as cracks at the side portion 113 may be minimized in following the plasma process.

Then, as illustrated in FIG. 5C, the passivation layer 450 and the insulation layer 440 may be planarized until a top surface of the via structure 120 may be exposed. For example, a CMP process may be performed on the wafer-carrier assembly 900 until the top surface of the via structure 120 may be exposed, so that the gap space between the neighboring via structures 120 may be filled with residuals of the insulation layer 440 and the passivation layer 450 and the protruded via structures 120 may be isolated from each other by the residuals of the insulation layer 440 and the passivation layer 450. That is, the insulation layer 440 and the passivation layer 450 may be formed into an insulation pattern 440a and a passivation pattern 450a by which the neighboring via structures 120 may be node-separated from each other.

Thereafter, as illustrated in FIG. 5D, a conductive pattern may be formed on each of the via structures 120 as the interconnector 500. A conductive layer may be formed on the via structures 120, the insulation pattern 440a and the passivation pattern 450a, and may be patterned into the conductive pattern 500 in such a way that the conductive pattern 500 may make contact with the via structure 120 on the backside 112 of the wafer structure 100.

The via structure 120 may function as a penetration electrode penetrating through the wafer structure 100 and the interconnector 500 may function as a contact pad making contact with the penetration electrode. Thus, the wafer structure 100 may be electrically connected to additional wafer structure and/or a circuit board by the via structure 120 and the interconnector 500.

The interconnector 500 may be patterned into various configurations and structures according to the configurations and structures of the wafer structure 100. For example, the via structure 120 and/or the interconnector 500 may be formed into a bump structure for electrically connecting with exterior systems. Further, the via structure 120 and/or the interconnector 500 may be formed into a part of a re-directional line that may be electrically connected to the conductive structures and the wiring lines of the wafer structure 100.

The conductive layer for the interconnector 500 may also be formed by the plasma deposition process, and in such a case, the optical shielding layer 400 may also function as a lower electrode for the plasma deposition process.

In the present example embodiment, the plasma etching process and the plasma deposition process for forming the insulation layer 440, the passivation layer 450 and the conductive layer for the interconnector 500 may be performed by using nitrogen (N) plasma.

A light having a wavelength of about 365 nm to about 370 nm may be generated from the nitrogen (N) plasma process. However, the light in the nitrogen (N) plasma process may be sufficiently prevented from reaching the adhesive 300 interposed between the wafer structure 100 and the carrier 200, and thus the photodegradable adhesive 300 may be sufficiently prevented from being self-released by the light.

The present example embodiment discloses that the adhesive 300 may be self-released by the light having the wavelength in a range of about 350 nm to about 400 nm and thus the optical shielding layer 400 may prevent the light having the wavelength in a rage of about 350 nm to about 400 nm from reaching the adhesive 300 in the nitrogen (N) plasma process from which the light having the wavelength of about 365 nm to about 370 nm may be generated. Therefore, the shielding wavelength of the optical shielding layer 400 may be varied according to the wavelength of the self-release of the adhesive 300 and the wavelength of the light generated from the plasma process.

Therefore, although the wafer structure 100 may be assembled to the light penetration carrier 200 by the photodegradable adhesive 300 in the wafer-carrier assembly 900, the adhesive 300 may sufficiently maintain the initial adhesive force between the wafer structure 100 and the carrier 200 in the consecutive plasma processes because the dissolving light for dissolving the adhesive 300 may be sufficiently prevented from reaching the adhesive 300 in the plasma processes. Accordingly, the swelling defect and the arching defect may be sufficiently prevented between the wafer structure 100 and the carrier 200.

In addition, since the insulation layer 440 and the passivation layer 450 may be further stacked on the optical shielding layer 400 at the side portion of the wafer structure 100, the wafer crack caused by stress variation in the plasma process may be sufficiently prevented even though the thickness of the wafer 110 may be reduced.

Then, the light may be irradiated onto the wafer-carrier assembly 900 to thereby separate the wafer structure 100 and the carrier 200 (step S400).

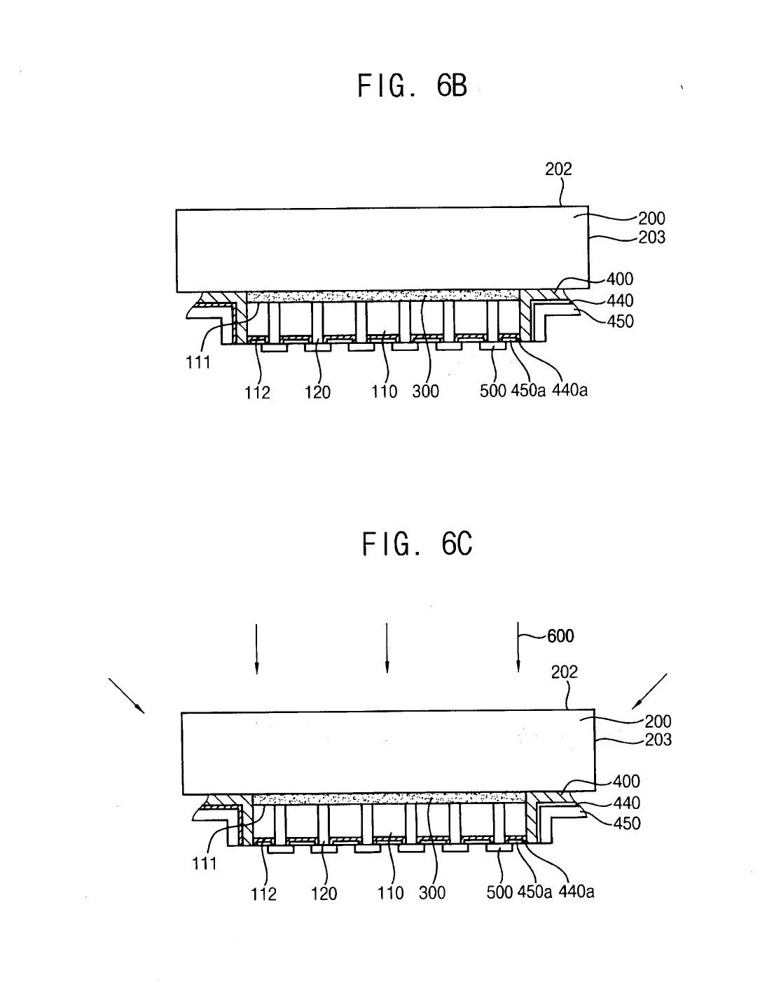

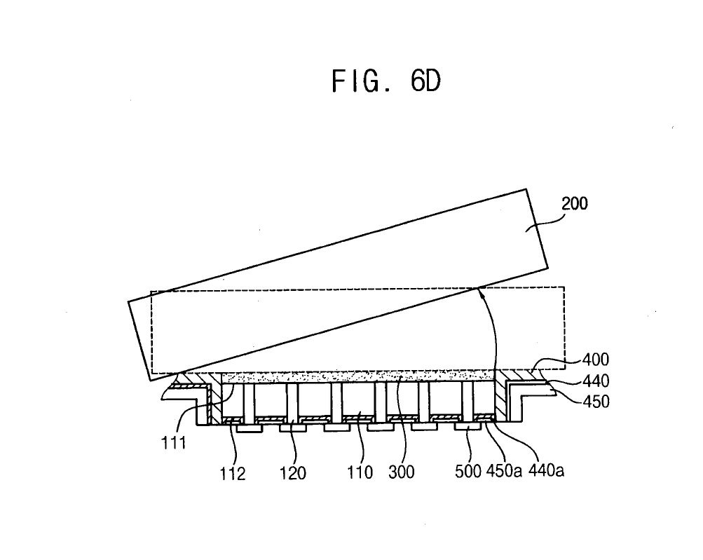

FIGS. 6A to 6D are cross sectional views illustrating processing steps for separating the wafer structure and the carrier in accordance with an example embodiment of the present inventive concept.

Referring to FIGS. 1 and 6A to 6D, once the interconnector 500 may be formed on the wafer-carrier assembly 900, the wafer-carrier assembly 900 may be loaded into a disassemble chamber for disassembling the wafer structure 100 and the carrier 200.

The wafer-carrier assembly 900 may be loaded into the disassemble chamber in such a way that the rear surface 202 of the carrier 200 may face upwards. Then, the optical shielding layer 400 may be partially removed from the rear surface 202 and the side portion or surface 203 of the carrier 200, thereby partially exposing the carrier 200. For example, the insulation layer 440 and the passivation layer 450 may be removed from the wafer-carrier assembly 900 by a first cleaning process and then the optical shielding layer 400 may be removed from the wafer-carrier assembly 900 by a second cleaning process. Since the insulation layer 440 may include an oxide, the passivation layer 450 may include a nitride and the optical shielding layer 400 may include a polymer, the first and the second cleaning processes may be performed by respective wet cleaning process in which the cleaning solutions may be different. In contrast, the first cleaning process may include a plasma cleaning process and the second cleaning process may include a wet cleaning process.

Then, the dissolving light for dissolving the photodegradable adhesive 300 may be irradiated into the exposed carrier 200. That is, the dissolving light may be irradiated into one of the rear surface 202 and the side portion 203 of the carrier 200, and thus the photodegradable adhesive 300 interposed between the carrier 200 and the wafer structure 100 may be dissolved by self-release due to the dissolving light. When the adhesive 300 is sufficiently dissolved, the wafer structure 100 may be disassembled from the carrier 200.

For example, an UV irradiator may be provided at a upper portion of the disassemble chamber and an UV light having a wavelength of about 350 nm to about 400 nm may be irradiated to the carrier 200 from the UV irradiator. The UV light may penetrate through the rear surface 202 and the side portion 203 of the carrier 200 and may reach the adhesive 300. Thus, the adhesive 300 may be self-released by the UV light and be dissolved into a sol state, so no adhesive force may be applied between the wafer structure 100 and the carrier 200. Then, the carrier 200 may be separated from the wafer structure 100 by a grip member.

In a modified example embodiment, after separating the wafer structure 100 and the carrier 200, an additional wafer structure and/or a circuit board may be further stacked on the separated wafer structure 100, thereby forming a chip package. In such a case, the wafer structure 100 and the additional wafer structure and/or the circuit board may be electrically connected with each other through the via structure 120 and the interconnector 500.

For example, the additional wafer electrically connected to the wafer structure 100 by the via structure 120 and the interconnector 500 may constitute a chip stack package and the circuit hoard electrically connected to the wafer structure 100 by the via structure 120 and the interconnector 500 may complete a semiconductor package. In case that a plurality of chips may be arranged on the wafer structure 100, the wafer structure 100 may be cut into pieces by the chip and each chip may be mounted on the circuit board in such a way that the circuit board may be electrically connected with the chip through the via structure 120 and the interconnector 500.

According to the example embodiments of the method of manufacturing semiconductor devices, the wafer structure may be adhered to the carrier by a photodegradable adhesive tape in place of the conventional adhesive deposition layer, thereby reducing the manufacturing cost of the wafer-carrier assembly for forming a penetration electrode in the semiconductor device. Particularly, the light penetration carrier may be provided with the wafer-carrier assembly and thus the photodegradable adhesive may be sufficiently self-released by a dissolving light that may penetrate through the carrier from exterior of the wafer-carrier assembly. In addition, the wafer-carrier assembly may be covered with the optical shielding layer for preventing the light in the plasma process from penetrating through the carrier, so that the photodegradable adhesive may be sufficiently prevented from dissolving in the plasma process. Accordingly, the swelling and the arching defect between the wafer structure and the carrier may be sufficiently prevented in the plasma process.

In addition, since the insulation layer and the passivation layer may be further stacked on the optical shielding layer at the side portion of the wafer structure, the wafer crack caused by stress variation in the plasma process may be sufficiently prevented although the thickness of the wafer may be reduced.

Further, since the optical shielding layer may be formed as the conductive layer and thus function as a lower electrode layer for the plasma process, no additional electrode layer such as the ITO layer may be required in the plasmas process. Therefore, the process complexity and high cost due to the ITO layer defects and the replacement of the defective ITO layer may be sufficiently reduced.

While the present example embodiments discloses the wafer-carrier assembly for forming the penetration electrode such as the through silicon via (TSV), the optical shielding layer could also be applied to various carrier assemblies in which the light penetration carrier may be adhered to an object by a photodegradable adhesive and the self-release of the photodegradable adhesive may be shielded from the light generated from the plasma process to the wafer-carrier assembly.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims.

What is claimed is:

1. A method of manufacturing a semiconductor device, the method comprising:
forming a preliminary wafer-carrier assembly such that an active face of a wafer structure having a plurality of via structures is adhered to a front surface of a light-penetrating carrier by a photodegradable adhesive and a backside of the wafer structure opposite the active face faces upwards;
forming a wafer-carrier assembly having an optical shielding layer for preventing a light penetration such that the wafer structure, the carrier and the adhesive are covered with the optical shielding layer except for the backside of the wafer structure through which the via structures are exposed;
forming an interconnector on the backside of the wafer structure such that the via structures make contact with the interconnector; and
separating the wafer structure and the carrier by irradiating a light to the wafer-carrier assembly.

2. The method of claim 1, wherein forming the wafer-carrier assembly having the optical shielding layer includes:
partially removing a rear portion of the wafer structure including the backside from the preliminary wafer-carrier assembly, until the via structures are exposed;
turning over the preliminary wafer-carrier assembly such that a rear surface of the carrier opposite the front surface faces upwards; and
forming the optical shielding layer along a surface profile of the preliminary wafer-carrier assembly such that the preliminary wafer-carrier assembly is enclosed by the optical shielding layer, except for the backside of the wafer structure.

3. The method of claim 2, wherein the optical shielding layer is formed on the preliminary wafer-carrier assembly by one of a spin-on-coating (SOC) process and a deposition process.

4. The method of claim 1, wherein forming the wafer-carrier assembly having the optical shielding layer includes:
immersing the preliminary wafer-carrier assembly into a solution having solutes of optical shielding particles, thereby forming a material layer along a surface profile of the preliminary wafer-carrier assembly;
drying the material layer, thereby forming the optical shielding layer on the preliminary wafer-carrier assembly; and
partially removing the optical shielding layer and a rear portion of the wafer structure under the optical shielding layer, thereby exposing the backside of the wafer structure and the via structures.

5. The method of claim 4, wherein partially removing the optical shielding layer and the rear portion of the wafer structure is performed by one of a grinding process, a chemical mechanical polishing (CMP) process and an etch-back process.

6. The method of claim 1, wherein the photodegradable adhesive includes a double-sided adhesive tape interposed between the active face of the wafer structure and the carrier.

7. The method of claim 6, wherein the photodegradable adhesive is configured to be self-released by an ultraviolet light.

8. The method of claim 7, wherein the ultraviolet light includes a wavelength in a range of 350 nm to 400 nm.

9. The method of claim 1, wherein the carrier includes one of glass and quartz.

10. The method of claim 1, wherein the optical shielding layer includes a conductive material.

11. The method of claim 10, wherein the conductive material includes a carbon-based polymer.

12. The method of claim 10, wherein the optical shielding layer is configured to prevent a light having a wavelength of 350 nm to 400 nm from reaching the wafer-carrier assembly, so that the photodegradable adhesive is prevented from self-releasing in a plasma process on the wafer-carrier assembly.

13. The method of claim 1, wherein forming the interconnector includes:
partially etching the backside of the wafer structure such that the via structures protrude from the backside;
forming an insulation layer along a surface profile of the protruded via structures such that the neighboring via structures are electrically insulated from each other;
forming a passivation layer on the insulation layer such that a gap space between the neighboring via structures is filled with the passivation layer;
planarizing the passivation layer and the insulation layer until a top surface of the via structure is exposed; and
forming a conductive pattern on the backside of the wafer structure such that the conductive pattern makes contact with the via structure.

14. The method of claim 1, wherein separating the wafer structure and the carrier includes:
partially removing the optical shielding layer from a rear surface and a side portion of the carrier, thereby partially exposing the carrier;
irradiating the light into the exposed carrier, thereby dissolving the photodegradable adhesive interposed between the carrier and the wafer structure; and
disassembling the wafer structure and the carrier.

15. The method of claim 14, wherein the light has a wavelength of 350 nm to 400 nm and is irradiated from an upper portion of the wafer-carrier assembly such that the light penetrates through the carrier and reaches the adhesive.

16. A method of manufacturing a semiconductor device, the method comprising:
forming a preliminary wafer-carrier assembly comprising a wafer structure and a light transmissive carrier, with a backside of the wafer adhered to a front surface of the carrier by a photodegradable adhesive;
forming a wafer-carrier assembly having an optical shielding layer that covers the carrier and at least a portion of the wafer structure, wherein the optical shielding layer is configured to block light having a wavelength of about 350 nm to about 400 nm from reaching the photodegradable adhesive;
partially removing the optical shielding layer from a rear surface and a side portion of the carrier such that a portion of the carrier is exposed; and
separating the wafer structure and the carrier by irradiating light to the exposed portion of the carrier.

17. The method of claim 16, before partially removing the optical shielding layer, the optical shielding layer covers the rear surface and a side portion of the carrier, a side portion of the photodegradable adhesive, and a side portion of the wafer structure.

18. The method of claim 17, wherein the optical shielding layer is formed on the preliminary wafer-carrier assembly by one of a spin-on-coating (SOC) process and a deposition process.

19. The method of claim 16, wherein the wafer structure comprises a plurality of via structures, the method further comprising, after forming the wafer-carrier assembly having the optical shielding layer and before partially removing the optical shielding layer, forming an interconnector on the backside of the wafer structure such that the via structures make contact with the interconnector.

20. The method of claim 19, wherein forming the wafer-carrier assembly having the optical shielding layer includes:
immersing the preliminary wafer-carrier assembly in a solution having solutes of optical shielding particles to form a material layer along a surface profile of the preliminary wafer-carrier assembly;
drying the material layer to form the optical shielding layer on the preliminary wafer-carrier assembly; and
partially removing the optical shielding layer and a rear portion of the wafer structure under the optical shielding layer to expose the backside of the wafer structure and the via structures.
